(19) United States
(12) Patent Application Publication
(10) Pub. No.: US 2015/0285855 A1
(43) Pub. Date: Oct. 8, 2015

(54) SYSTEM WITH DUAL FUNCTION LOAD BOARD

(71) Applicant: Charles Tzu-tai KAO, Taipei City (TW)

(72) Inventor: Charles Tzu-tai KAO, Taipei City (TW)

(21) Appl. No.: 14/288,198

(22) Filed: May 27, 2014

Related U.S. Application Data
(60) Provisional application No. 61/974,543, filed on Apr. 3, 2014.

(51) Int. Cl. G01R 31/28

(52) U.S. Cl. CPC G01R 31/2834

(57) ABSTRACT

A system with dual function load board is provided herein, and the system with dual function load board comprises a programmable module, a dual function load board and a software application with user interface. The programmable module is configured for emulating an Automatic Test Equipment (ATE) when performing ATE test. The dual function load board is electrically connected to the FPGA module and configured for performing the ATE test and a Bench test. The software application with user interface (UI) is configured for providing an interface to perform tests.

### FIELD OF THE DISCLOSURE

The present invention relates to the field of a system with dual function load board, and more particularly relates to a system with dual function load board to perform both of Bench test and Automatic Test Equipment (ATE) test.

### BACKGROUND OF THE INVENTION

The test of Integrated Circuit (IC) chips can be divided into Bench test and ATE test. A Bench test is processed by Research and Development (R&D) engineers. A Bench test is the process of characterizing the failure mode of the IC sample using various pieces of bench equipment for exciting the device and measuring its responses. The equipment required for effective failure verification includes various power supplies, multi-meters, frequency counters, oscilloscopes, curve tracers, break-out boxes, and the like. Sometimes it is also necessary to build a circuit that simulates the application of the customer where the failure was observed. The idea is to be able to observe the failure of the sample inside the Failure Analysis (FA) lab without an ATE. An ATE test is performed on the Device Under Test (DUT) by the testing department. An ATE test uses automation to quickly perform measurements and evaluate the test results. ATE is capable of automatically testing and diagnosing faults in sophisticated electronic packaged parts or on Wafer testing, including System-On-Chip and Integrated Circuits. The hardware and software used in these two tests run up costs and labor. Also, these tests would delay product release time to market.

FIG. 1 is a block diagram illustrating the conventional Bench test and ATE test. As shown in FIG. 1, a Bread Board is used in the Bench test and a Load Board is used in the ATE test. After the Bench test and the ATE test are complete, the test results are required in order to perform a test correlation. Thereafter, the IC is ready for production. Accordingly, there are two different test boards used in the ATE test and the Bench test. Since the functions in a Load Board and a Bread Board are different, there is not a test board released in market which includes dual functions for testing in both the ATE test and the Bench test.

Therefore, a need has arisen to design a test board used in both the ATE test and the Bench test to save cost and time.

### SUMMARY OF THE INVENTION

One objective of the present invention is to provide a system with dual function load board, so both of the Bench test and the ATE test can be operated in the system with dual function load board.

In order to solve the technical problem described above, one technical propose provided in the present invention is a system with dual function load board, and the system with dual function load board comprises a programmable module, a dual function load board and a software application with user interface. The programmable module is configured for emulating an Automatic Test Equipment (ATE) when performing ATE test. The dual function load board is electrically connected to the FPGA module and configured for performing the ATE test and a Bench test. The software application with user interface (UI) is configured for providing an interface to perform tests.

Another objective of the present invention is to provide a system with dual function load board, so both of the Bench test and the ATE test can be operated in the system with dual function load board so as to minimize the inaccuracy of the test correlation between the Bench test and the ATE test.

In order to solve the technical problem described above, another technical propose provided in the present invention is a system with dual function load board, and an ATE test or a Bench test can be performed thereon. The system with dual function load board comprises a programmable module, a dual function load board, a software application with UI, a switch, a DC supply and a Bench instrument. The programmable module is configured for emulating an Automatic Test Equipment (ATE) when performing ATE test. The dual function load board electrically is connected to the FPGA module and configured for performing the ATE test and a Bench test. The software application with UI is configured for providing an interface to perform tests. The switch is configured for the system to switch between the ATE test and the Bench test. The DC supply is configured for providing extra power in the system. The Bench instrument is used when performing the Bench test.

### DESCRIPTION OF THE DRAWINGS

FIG. 1 is a block diagram illustrating the conventional Bench test and ATE test;

FIG. 2 is a test flow illustrating a dual function Load Board (DFLB) in this invention;

FIG. 3 is a block diagram illustrating a system with a dual function load board in the present invention;

FIG. 4 is a block diagram illustrating the system with a dual function load board simulating as a V93K tester;

FIG. 5 is a table of the features of the dual function load board; and

FIG. 6A and FIG. 6B are views illustrating the connection between the standard FPGA module and the dual function load board;

FIG. 7 is a functional block diagram illustrating the standard FPGA module;

FIG. 8 is a functional block diagram illustrating a few of the external enhancement modules used in the system with a dual function load board of the present invention;

FIG. 9 is a block diagram illustrating the functions of the firmware in the present invention;

FIG. 10A˜FIG. 10C are views illustrating some examples of the switches used in the system with a dual function load board; and

FIG. 11 is a flow chart illustrating that the Bench test in the system with a dual function load board.

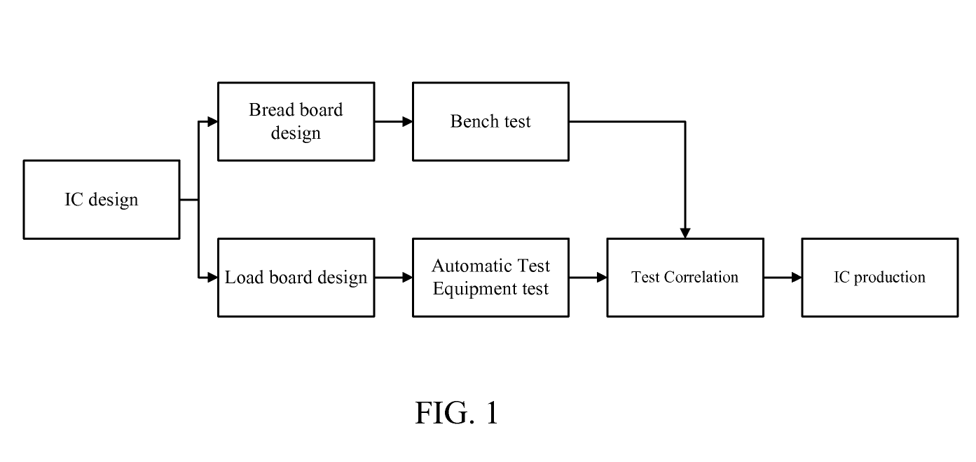

### DETAILED DESCRIPTION OF THE PREFERRED EMBODIMENTS

The above-mentioned description of the present invention can be best understood by referring to the following detailed description of the preferred embodiments and the accompanying drawings.

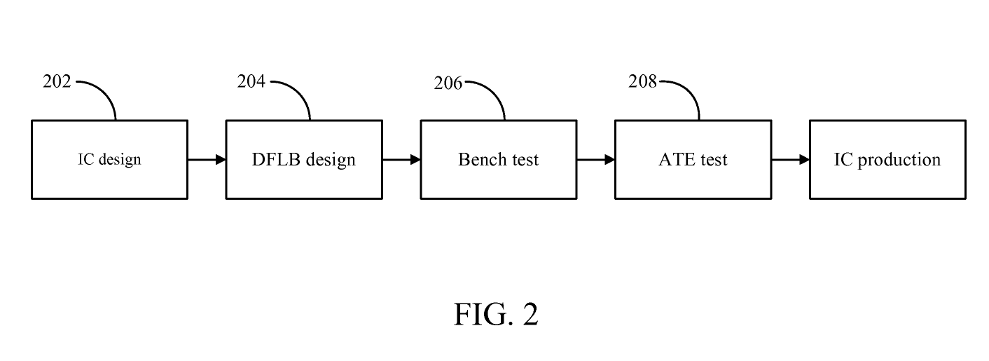

FIG. 2 is a test flow illustrating a system with dual function Load Board (DFLB) in this invention. As shown in FIG. 2, in a stage 202, an IC design is processed. The IC design in this stage is performed by Engineers and the ICs can be any different kinds of ICs, such as digital ICs or analog ICs, and it is not limited herein. After the IC design is performed, a dual function load board is developed in stage 204 to test the ICs and the dual function load board in the present invention can be used in both the Bench test in stage 206 and the ATE test in stage 208. Since the conventional load board is larger than the conventional bread board, the dual function load board in the present invention is a modified load board which includes the functions in both of the conventional load board and the bread board. The dual function load board is developed and worked in cooperation with a Field-programmable gate array (FPGA) Module. In addition, the dual function load board in the present invention includes a switch able to be operated in both the Bench test and the ATE test. Therefore, the Bench test and the ATE test can be operated in the dual function load board. Since the Bench test and the ATE test are operated in the same load board, the inaccuracy of the test correlation between the Bench test and the ATE test can be minimized After the test correlation between the Bench test and the ATE test is complete, the IC is ready to be produced in stage 210.

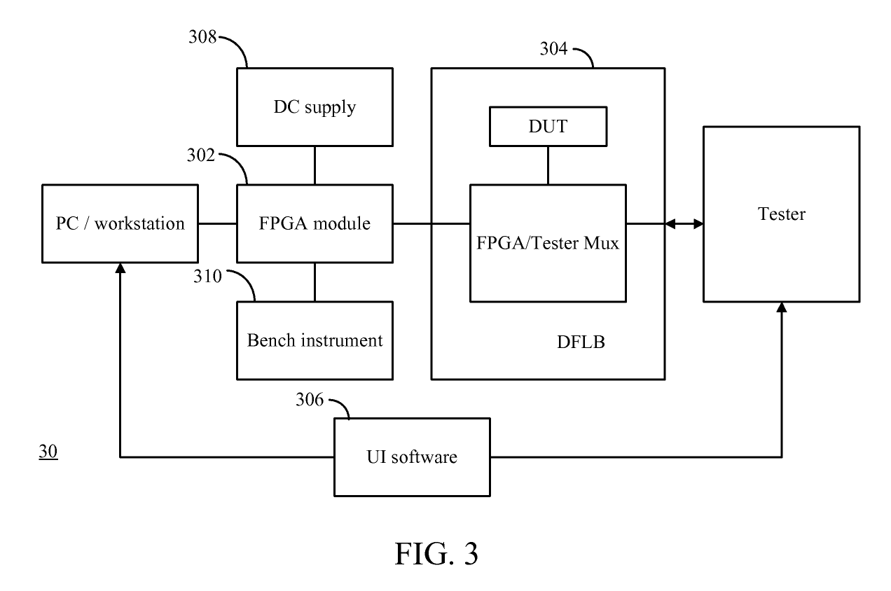

FIG. 3 is a block diagram illustrating a system with a dual function load board in the present invention. As shown in FIG. 3, the system with a dual function load board 30 includes a FPGA module 302, a dual function load board 304, and a software application with user interface (UI) 306. The FPGA module 302 is worked as a simulator to emulate an Automatic Test Equipment (ATE) when performing the ATE test. The FPGA module 302 is a programmable module and can be installed with any different firmware, such as V93000 Smartest OS and so on, to emulate any ATEs. Therefore, the dual function load board 304 can be worked as the load board in the ATE test and the bread board in the Bench test. The test IC can be installed on the dual function load board 304. The dual function load board 304 is electrically connected to the FPGA module 302. The software application with a UI 306 provides a standard interface for test engineers to perform many different kinds of tests. Alternatively, the system with a dual function load board 30 further includes a DC supply 308 to provide extra power and a Bench instrument 310 for the Bench test. When the system with the dual function load board 30 requires extra power when performing some of the tests, the DC supply 308 can provide extra power therein. The Bench instrument 310 is used when performing some specific Bench tests. The system with the dual function load board 30 in the present invention can be connected to a personal computer, a workstation or a test machine by a Universal Serial Bus (USB) cable or any other cables or interfaces to perform the Bench test or the ATE test.

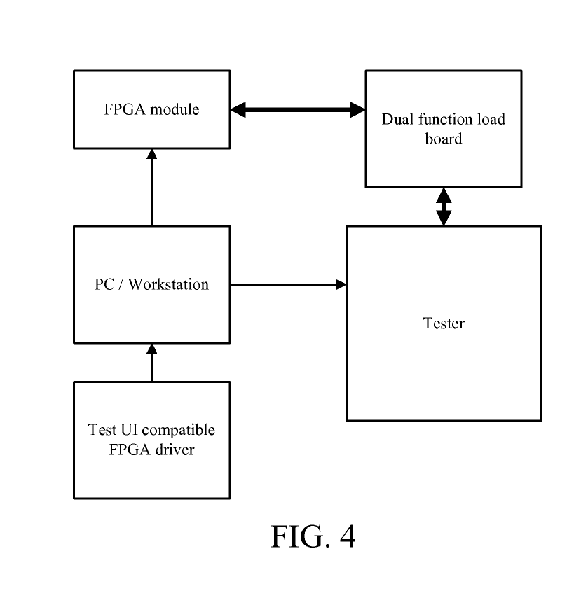

FIG. 4 is a block diagram illustrating the system with a dual function load board simulating as a V93K tester. As shown in FIG. 4, the test engineer connects the system with a dual function load board to a personal computer or a workstation and installs the driver or firmware having the software application with UI for the system with the dual function load board in the personal computer or the workstation so as to perform the Bench test. If the test IC is required to do the ATE test, the system with a dual function load board and the test IC are connected to the Tester (also called a testing machine) so as to perform the ATE test. Therefore, the hardware of the V93K tester can be simulated by the system with the dual function load board and the software application with the UI can perform to manipulate the test procedure of the V93K tester.

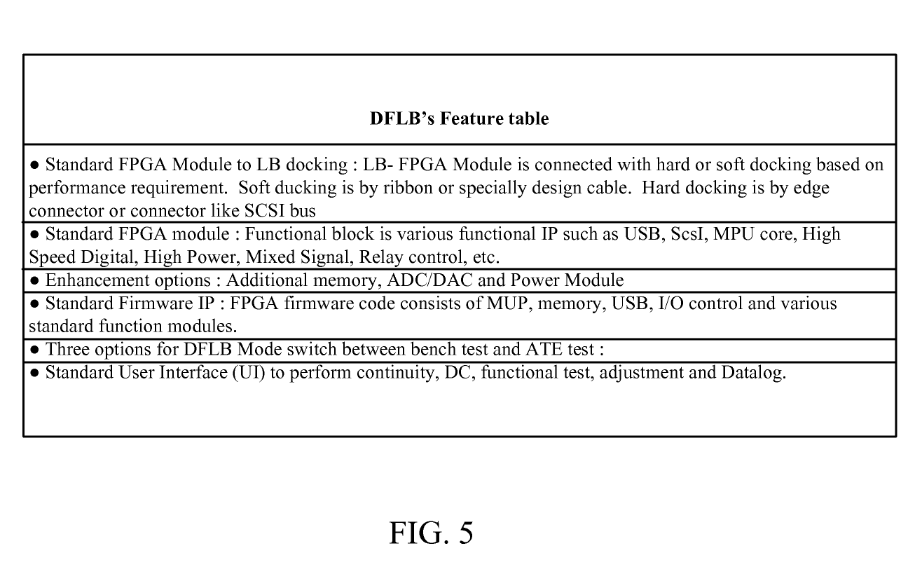

FIG. 5 is a table of the features of the dual function load board. As shown in FIG. 5, the feature of the dual function load board includes the following features, but it is not limited herein. The FPGA module is connected to hard docking or soft docking in accordance with the performance requirement. For example, the soft docking can be ribbons or any special design cables, and the hard docking can be an edge connector or a connector like SCSI bus. It is not limited herein. The functional block in the FPGA module of the present invention can be various function internal protocol (IP), such as PC USB interface (I/F), SCSI, MPU (Micro Processor Unit) core, High Speed Digital, High Power, Mixed Signal, Relay control, etc. Alternatively, the DFLB module includes some enhancement options, such as additional memory, Hi-speed digital, Hi-resolution ADC/DAC, Hi-power DC, Hi-resolution DC measurement and RF/Wireless module board, connected to the FPGA module with cable or a mother board. Moreover, the firmware code of the FPGA module consists of MPU, memory, USB, I/O control and various standard functions modules. Moreover, in the system with the dual function load board, the switch includes several switching options on the dual function load board to switch between Bench test mode or ATE test mode.

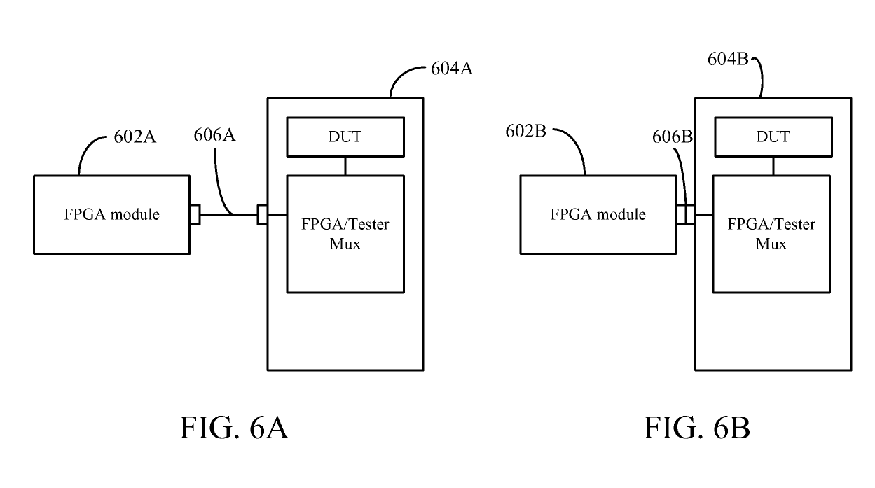

FIG. 6A and FIG. 6B are views illustrating the connection between the standard FPGA module and the dual function load board. As shown in FIG. 6A, the FPGA module 602A and the load board 604A are connected together by a soft connector 606A based on the test performance requirements. The soft connector 606A is by ribbon or any other special design cables, and it is not limited herein. As shown in FIG. 6B, the FPGA module 602B and the load board 604B are connected together by a hard connector 606B based on the test performance requirements. The hard connector 606B is by an edge connector or a connector like SCSI bus and so on.

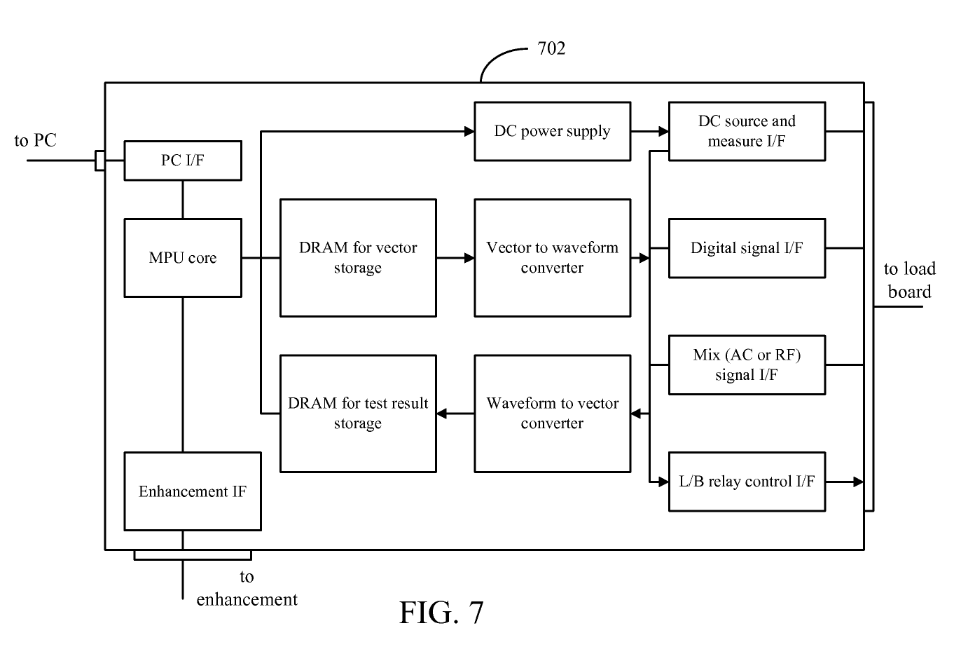

FIG. 7 is a functional block diagram illustrating the standard FPGA module. As shown in FIG. 7, the FPGA module 702 in this invention includes various features, such as an interface for connecting with a personal computer, Small Computer System Interface (SCSI), Math Processor Unit (MPU), High Speed Digital, signal converter (vector/waveform or waveform/vector), High Power, Mixed Signal, Relay control, and so on. The features shown in FIG. 7 are to illustrate the function of the FPGA module 702, and it is not to limit herein.

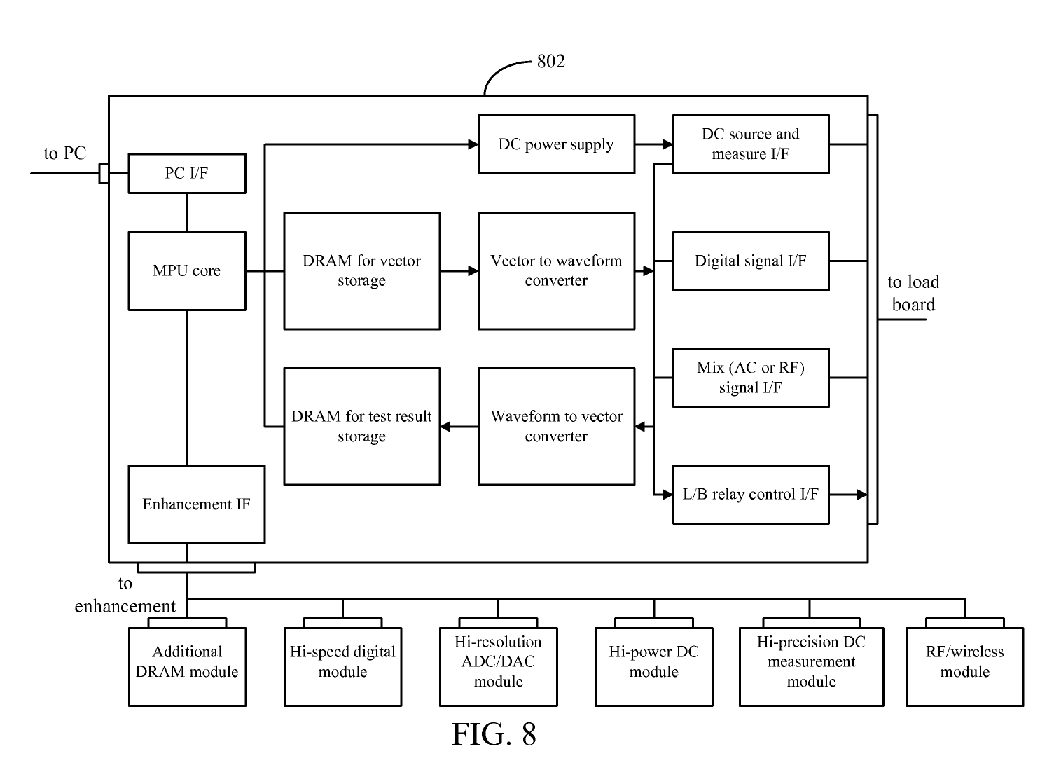

FIG. 8 is a functional block diagram illustrating a few of the external enhancement modules used in the system with a dual function load board of the present invention. As shown in FIG. 8, the function of the system 802 with a dual function load board may lack some extra functions when performing some specific tests. Alternatively, the system 802 in the present invention includes some enhancement options to add some extra functions when performing the tests. For example, the enhancement options include additional memory, Hi-speed digital, Hi-resolution analog-to-digital converter (ADC) or digital-to-analog converter (DAC), Hi-power DC power supply, Hi-resolution DC measurement and RF/Wireless module boards, and so on. It should be noted that those enhancement options in the drawing are shown as some examples, and it is not to limit that only those optional functions can be added in the system of the present invention. As long as the enhancement options can be used in the Bench test or the ATE test, they can be options used in the present invention, and it is not limited herein.

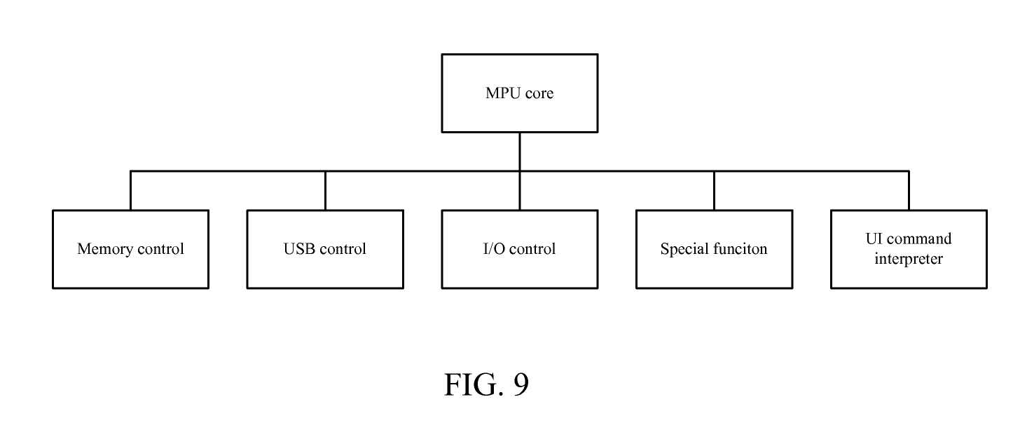

FIG. 9 is a block diagram illustrating the functions of the firmware in the present invention. As shown in FIG. 9, the firmware code of the standard FPGA module at least includes functions corresponding to the MPU, memory, USB I/O control, and other standard function modules. For example, the MPU core, High Speed Digital, High Power, Mixed Signal, and the relay driver MPU are for test program control, and memory control is to store ATE test vector patterns and test code. The USB control is for communication with PC, and the I/O control is for FPGA module I/O pins to emulate ATE I/O pins, such as digital (test channel pins or high speed digital pins), analog (AC signal pins for ADC/DAC mixed signal pins), power (DC power), and RF(radio TX/RX pins) functions. In addition, the standard FPGA module firmware code also includes some other special functional blocks for standard technologies, such as DDR3, HDMI, Ethernet, USB2, or UI Command Interpreter for UI command decoding/encoding and execution.

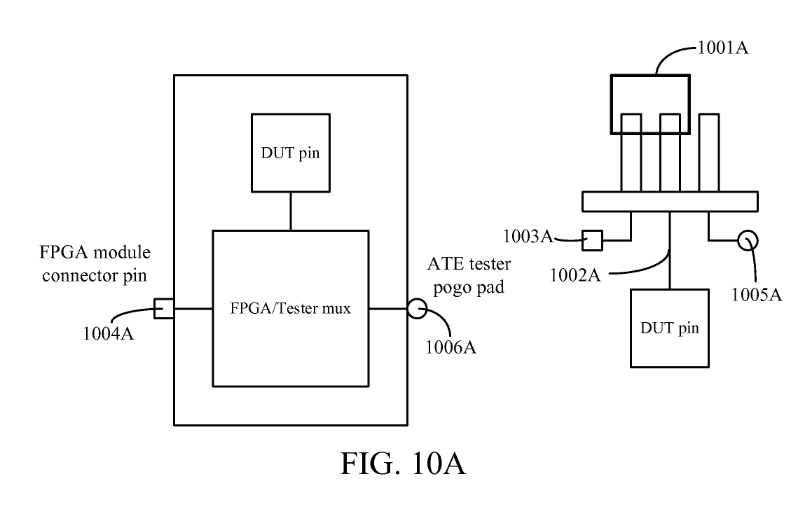

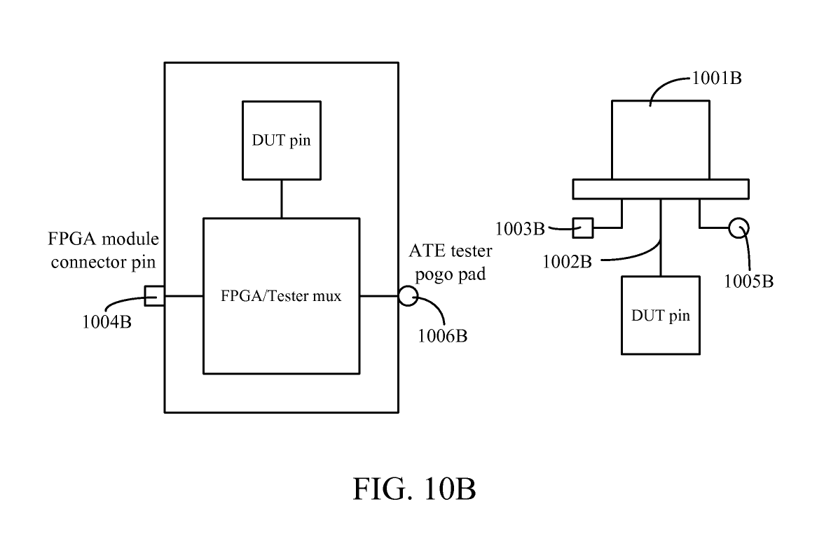

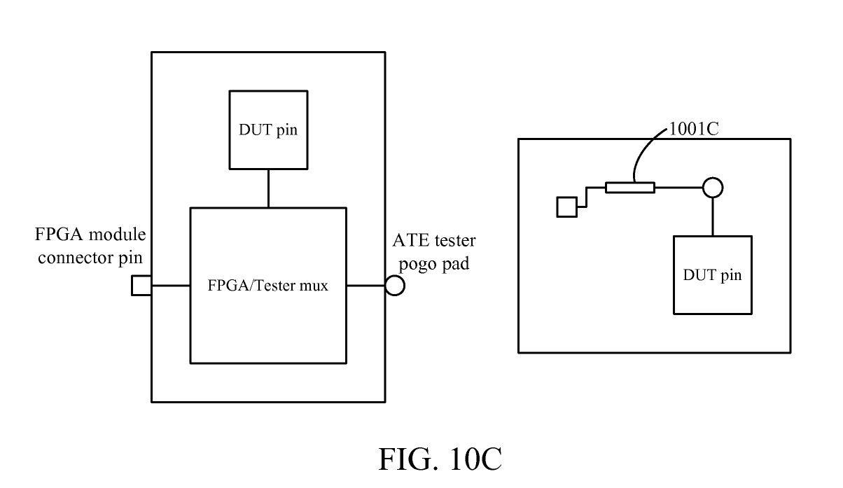

FIG. 10A˜FIG. 10C are views illustrating some examples of the switches used in the system with a dual function load board. The switches implemented in the present invention include three way hardware options to switch between the Bench test and the ATE test. As shown in FIG. 10A, the switch 1001A used in the system with a dual function load board is a jumper 1001A with a 3-pin header, and a center pin 1002A of the jumper can be connected to a DUT (Device under Test) pin, a left pin 1003A thereof can be connected to a FPGA module connector pin 1004A and a right pin 1005A thereof can be connected to a pad (such as pogo pad) 1006A of the ATE tester. The diagram in the drawing shows that the DFLB is connected to the FPGA module. For the ATE test, the jumper is moved to the right position and the DUT pin can be connected to the pogo pad of the ATE tester. Accordingly, this approach implements the Jumper to switch between the ATE test and the Bench test.

As shown in FIG. 10B, the switch used in the system with a dual function load board is a jumper 1001B with 3-pin relay. A center pin 1002B of the Jumper can be connected to the DUT pin, a Normal Close (NC) pin 1003B can be connected to FPGA module connector pin 1004B, and a Normal Open (NO) pin 1005B can be connected to a pogo pad 1006B of the ATE tester. The diagram shows that the DFLB is connected to the FPGA module when the relay pin is not powered and engaged. For the ATE test, the relay position is in the NO pin and the DUT pin can be connected to the pogo pad of the ATE tester. This approach allows maximum flexibility to switch between two modes without manual adjustment.

As shown in FIG. 10C, the switch used in the system with dual function load board is a zero ohm resistor 1001C for a high speed or sensitive signal. As shown in FIG. 10C, the FPGA module connector pin is connected to the pogo pad of the ATE tester through the zero ohm resistor for a high speed or sensitive signal. The Load Board in the present invention can perform the Bench test with the resistor installed thereon. After the Bench test, the zero ohm resistor can be removed so that there will be no stub that could cause a signal reflection issue for the ATE test. This diagram shows that the DFLB module is ready for the Bench test with the resistor installed for high speed application.

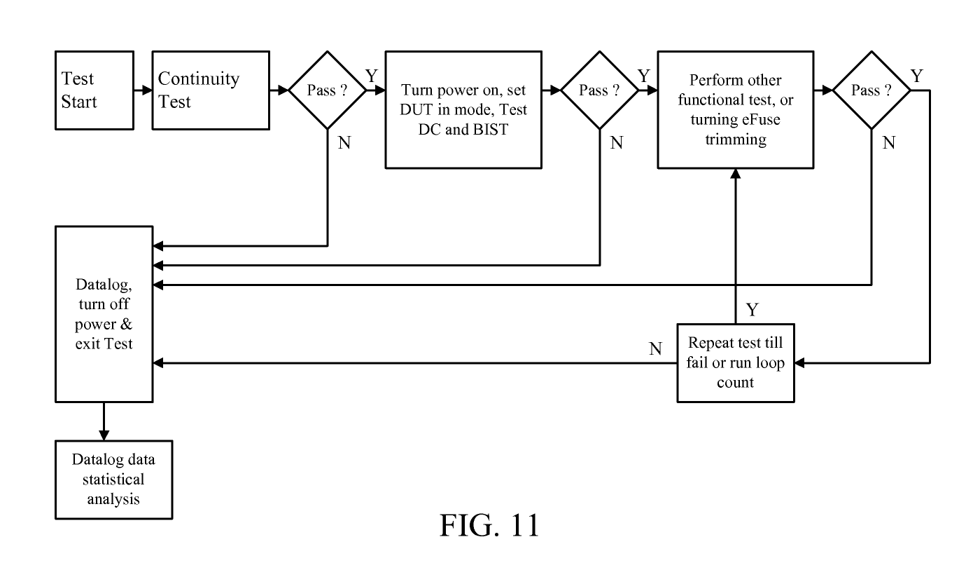

FIG. 11 is a flow chart illustrating that the Bench test in the system with a dual function load board. As shown in FIG. 11, the user turns on the power of the system and a personal computer or a workstation when the test is started. After turning on the power, the DUT is put on the dual function load board and the Bench test begins. During the Bench test, if any one of the tests fails, the test is ended and the engineer has to analyze the design of the IC. When one of the tests is completed, another test is performed. After all of the tests are completed, the Bench test is finished. Therefore, the DUT can be sampled to perform the ATE test.

The present invention has been described with preferred embodiments thereof, and it is understood that many changes and modifications to the described embodiments can be carried out without departing from the scope and the spirit of the disclosure that is intended to be limited only by the appended claims.

What is claimed is:

1. A system with dual function load board, comprising:
a programmable module configured for emulating an Automatic Test Equipment (ATE) when performing ATE test;
a dual function load board electrically connected to the FPGA module and configured for performing the ATE test and a Bench test; and
a software application with user interface (UI) configured for providing an interface to perform tests.

2. The system with dual function load board according to claim 1, wherein the dual function load board is worked as a load board in the ATE test and a bread board in the Bench test.

3. The system with dual function load board according to claim 1, wherein the programmable module is a FPGA module and is installed with a firmware to emulate an ATE.

4. The system with dual function load board according to claim 1, further comprising a Bench instrument used when performing the Bench test.

5. The system with dual function load board according to claim 1, further comprising a DC supply to provide extra power.

6. The system with dual function load board according to claim 1, wherein the system with dual function load board is connected to a workstation and the software application with UI is installed in the workstation so as to operate the system.

7. The system with dual function load board according to claim 1, wherein the dual function load board includes a switch for the system to operate in both the Bench test and the ATE test.

8. The system with dual function load board according to claim 1, wherein the switch is a jumper with a three way hardware options or a three-pin relay.

9. The system with dual function load board according to claim 1, wherein the switch is a zero ohm resistor.

10. A system with dual function load board, and an ATE test or a Bench test can be performed thereon, and comprising:
a programmable module configured for emulating an Automatic Test Equipment (ATE) when performing ATE test;
a dual function load board electrically connected to the FPGA module and configured for performing the ATE test and a Bench test;
a software application with user interface (UI) configured for providing an interface to perform tests;
a switch configured for the system to switch between the ATE test and the Bench test;
a DC supply configured for providing extra power in the system; and
a Bench instrument used when performing the Bench test.

11. The system with dual function load board according to claim 10, wherein the dual function load board is worked as a load board in the ATE test and a bread board in the Bench test.

12. The system with dual function load board according to claim 1, wherein the programmable module is a FPGA module and is installed with a firmware to emulate an ATE.

13. The system with dual function load board according to claim 10, wherein the system with dual function load board is connected to a workstation and the software application with UI is installed in the workstation so as to operate the system.

14. The system with dual function load board according to claim 10, wherein the switch is a jumper with a three way hardware options.

15. The system with dual function load board according to claim 10, wherein the switch is a jumper with a three-pin relay, and

[symbol]

16. The system with dual function load board according to claim 15, wherein the jumper includes a center pin, a normal close (NC) pin and a normal open (NO) pin, and the center pin of the jumper can be connected to a DUT pin in the dual function load board, the NC pin can be connected to the programmable module and the NO pin can be connected to the ATE tester.

17. The system with dual function load board according to claim 1, wherein the switch is a zero ohm resistor.
